(19) United States
(12) Patent Application Publication
(10) Pub. No.: US 2007/0208980 A1
(43) Pub. Date: Sep. 6, 2007

(54) Method of transmitting data between different clock domains

(76) Inventors: Peter Gregorius, Munich (DE); Martin Streibl, Petershausen (DE); Thomas Rickes, Munich (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(21) Appl. No.: 11/343,946

(22) Filed: Jan. 30, 2006

(51) Int. Cl. G01R 31/28

(52) U.S. Cl. 714/731

(57) ABSTRACT

A method of transmitting data between different clock domains includes receiving data bits on the basis of a receiving clock, sequentially storing the data bits in a ring buffer, simultaneously transmitting a number of the stored data bits from the ring buffer on the basis of a first transmitting clock, and transmitting the stored data bits from the ring buffer on the basis of a second transmitting clock.

### BACKGROUND

In present high-speed memory devices, such as in memory devices of the DRAM and DDR type, data is typically transmitted between different clock domains. In particular, multi-channel serial connections are typically used to transmit data between a memory controller and memory modules of a memory device. At the same time, a frame-based parallel data connection is typically used to transmit data within a memory module to and from a memory core, such as a DRAM array. For this purpose, the serial data stream is converted to a parallel data stream, taking into account the different clocks for transmitting the serial and parallel data streams. According to one memory configuration, the serial data stream on one channel of a multi-channel serial connection is converted to data frames of nine data bits which are transmitted in parallel to the memory core. In this configuration, the data frames are transmitted at a frequency which corresponds to 1/9^{th} of the frequency at which data bits are received from the serial data stream.

One problem with the above configuration is that the frequency at which data bits are received is an odd multiple of the frequency at which the data frames are transmitted. In particular, when generating a transmitting clock for transmitting the data frames from a receiving clock, on the basis of which the data bits are received, there will be a certain amount of mismatch between the receiving clock and the transmitting clock. Hence, it is extremely difficult to accomplish the conversion of the serial data stream into the frames on the basis of conventional techniques.

In view of this problem, it has been proposed to use a ring buffer for accomplishing the conversion of the serial data stream into a frame-based parallel format. An example of such a ring buffer is schematically illustrated generally at 100 in FIG. 5.

As illustrated, the ring buffer 100 comprises a number of data registers which are numbered from 0 to 19. In order to be able to store at least one frame consisting of nine data bits, ring buffer 100 comprises k=20 data registers. Data bits are stored in the ring buffer in a sequential manner via a write pointer 101 being advanced by one bit position at each cycle of the receiving clock. For reading out the stored data bits, nine bits are read out in parallel at each cycle of the transmitting clock, and a read pointer 102 is advanced by nine bits.

The ring buffer offers the advantage that the positions of the write pointer 101 and the read pointer 102 may vary relative to each other (i.e., a phase mismatch between the receiving clock and the transmitting clock is possible). Typically, a larger k will allow for a larger phase mismatch.

In FIG. 5, a section of old data bits, indicated at 112, have already been transmitted from the ring buffer 100, but have not yet been overwritten. A frame of nine data bits, indicated at 114, start from the position of the read pointer 102. A section of new data bits, indicated at 116, have already been written into the ring buffer 100, but have not yet been transmitted. The write pointer 101 and the read pointer 102 are advanced in a clockwise direction.

There have been proposed architectures for memory devices, in which data is not only transmitted from a memory controller to a memory module, but also from one memory module to a next memory module of a series configuration. One example of such an architecture is referred to as a parallel loop-forward configuration, which is schematically illustrated in FIG. 6.

As illustrated in FIG. 6, a memory device 200 comprises two memory modules 210a, 210b, which are arranged in a series configuration. The first memory module 210a of the series configuration receives data CA/WD from a memory controller (not illustrated) on the basis of a clock signal CL. The data CA/WD is forwarded from the first memory module 210a to the second memory module 210b of the series configuration. A read data signal RD from the first memory module 210a is transmitted to the second memory module 210b on the basis of the clock signal CL. The read data signal RD is transmitted from the second memory module 210b to the memory controller (not illustrated). Accordingly, different signal paths A, B are involved when performing a read operation on the memory module 210a and on the memory module 210b. The connection between the memory controller and the memory modules 210a, 210b is a multi-channel serial connection. Within the memory modules 210a, 210b, data originating from one channel of the multi-channel serial connection is transmitted in a frame-based format using nine parallel data bits.

Consequently, in architectures, such as illustrated in FIG. 6, there is a need for an effective way of converting a received serial data stream into frames of parallel data bits, which further allows for retransmitting or forwarding the received data stream.

### SUMMARY

One aspect of the present invention provides a method of transmitting data between different clock domains. The method includes receiving data bits on the basis of a receiving clock. The method includes sequentially storing the data bits in a ring buffer. The method includes simultaneously transmitting a number of the stored data bits from the ring buffer on the basis of a first transmitting clock. The method includes transmitting the stored data bits from the ring buffer on the basis of a second transmitting clock.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 schematically illustrates a device for transmitting data between different clock domains according to an embodiment of the invention.

FIG. 2 schematically illustrates cyclic registers in a ring buffer according to an embodiment of the invention.

FIG. 3 schematically illustrates a circuit for implementing a cyclic register according to an embodiment of the invention.

FIG. 4 schematically illustrates an embodiment of a circuit for implementing the device of FIG. 1.

FIG. 5 schematically illustrates an example ring buffer.

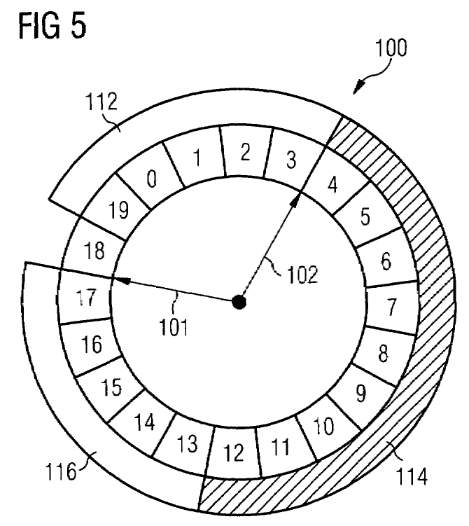

FIG. 6 schematically illustrates an example memory device according to a parallel-loop-forward architecture.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

Embodiments of the invention relate to transmitting data between different clock domains in a memory device. Embodiments of the invention are particularly suitable for use in high-speed memory applications, such as memories of the DRAM (dynamic random access memory) and DDR (double data rate) type.

One embodiment of a method transmits data between different clock domains. The method comprises receiving data bits on the basis of a receiving clock, sequentially storing the data bits in a ring buffer, simultaneously transmitting a number of the stored data bits from the ring buffer on the basis of a first transmitting clock, and transmitting the stored data bits from the ring buffer on the basis of a second transmitting clock. Accordingly, the method according to this embodiment accomplishes both a conversion between a serial and a parallel data format and allows for crossing between different clock domains by retransmitting the stored data bits on the basis of the second transmitting clock.

In one embodiment, the second transmitting clock has the same frequency as the receiving clock, but there may be a phase shift between the receiving clock and the second transmitting clock. Depending on the number n of data bits transmitted in parallel from the ring buffer, the first transmitting clock is preferably selected in such a way that it has on average 1/N times the frequency of the receiving clock. By using the ring buffer, it is possible to use an odd number of data bits to be simultaneously transmitted, thereby allowing for a phase mismatch and phase variations between the receiving clock and the first transmitting clock.

According to one embodiment, the ring buffer is subdivided into a number of N cyclic registers in such a way that adjacent data bits of the ring buffer are located in different cyclic registers. In this case, the method comprises accessing the cyclic registers for write operations on the basis of a corresponding divided clock having 1/N times the frequency of the receiving clock and advancing a write pointer of each cyclic register at each cycle of the corresponding divided clock.

In one embodiment, the divided clocks corresponding to the different cyclic registers are phase-shifted with respect to each other. The phase shift may be 1/N times the clock cycle of the divided clocks. This embodiment has the advantage that for implementing the ring buffer no circuits are required which operate faster than the frequency of the divided clock. In particular, it is not necessary to have circuit components which operate at the full frequency of the receiving clock, (i.e., the receiving clock may be a virtual clock which is actually not present in the system in the form of a clock signal).

One embodiment of a device configured to transmit data between different clock domains comprises a receiver for receiving data bits on the basis of a receiving clock, a ring buffer for sequentially storing the data bits, a first transmitter for simultaneously transmitting a number of the stored data bits from the ring buffer on the basis of a first transmitting clock, and a second transmitter for transmitting the stored data bits from the ring buffer on the basis of a second transmitting clock. In one embodiment, the device is configured to operate according to the above-explained method.

One embodiment of a memory module comprises the above described device configured to transmit data between different clock domains. The memory module comprises a memory core for storing data, a receiver for receiving data bits from a memory controller or a further memory module on the basis of a receiving clock, a ring buffer for sequentially storing the data bits, a first transmitter for simultaneously transmitting a number of the stored data bits from the ring buffer to the memory core on the basis of a first transmitting clock, and a second transmitter for transmitting the stored data bits from the ring buffer to a further memory module on the basis of a second transmitting clock.

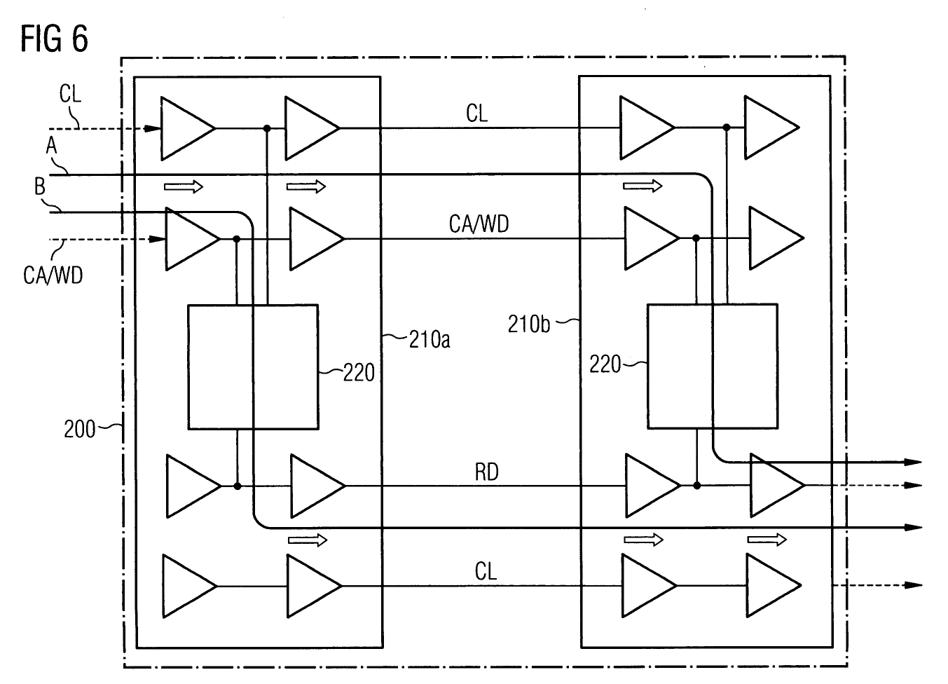

In one embodiment, a memory device has an architecture as illustrated in FIG. 6. One embodiment of a device converts a serial data stream of a multi-channel serial connection into data frames including a number of parallel bits to be simultaneously transmitted to a memory core (e.g., a DRAM array), and retransmits the received serial data stream between different memory modules. Various other applications of the invention are possible.

In the following description, it is assumed that data is transmitted between the memory controller and the memory modules of the memory device via a multi-channel serial connection which operates on the basis of a receiving clock. Within the memory modules, the data is transmitted in the form of data frames including parallel data bits on the basis of a first transmitting clock. The frequency of the first transmitting clock corresponds on average to 1/9^{th} times the frequency of the receiving clock. The data is retransmitted or forwarded from one memory module to the next memory module of a series configuration on the basis of a second transmitting clock which has the same frequency as the receiving clock, but may have a phase shift with respect to the receiving clock. Embodiments of electronic circuits configured to implement the invention are operated on the basis of a divided clock having a slower frequency which corresponds to ¼^{th} times the frequency of the receiving clock. In one embodiment, four divided clocks are phase-shifted with respect to each other by ¼^{th} clock cycle of the divided clocks. Consequently, the phase shift between the divided clocks corresponds to one clock cycle of the receiving clock.

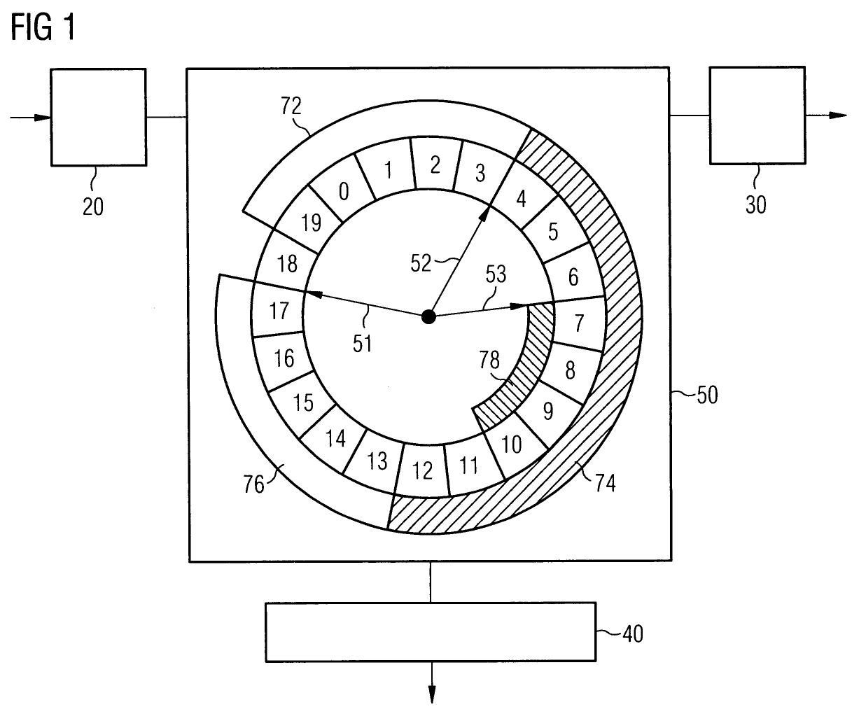

FIG. 1 schematically illustrates one embodiment of a device for transmitting data between different clock domains in a memory device. The device illustrated in FIG. 1 comprises a receiver 20 for receiving a serial data stream from a memory controller or an adjacent memory module of the memory device. The device comprises a ring buffer 50 configured to store the received data bits. Further, the device comprises a first receiver 40 configured to transmit the data bits stored in the ring buffer in the form of data frames to the memory core of the memory module and a second transmitter 30 configured to transmit the stored data bits to an adjacent memory module of the memory device. The receiver 20 is configured to receive the serial data stream on the basis of a receiving clock. The first transmitter 40 is configured to transmit the data frames on the basis of a first transmitting clock. The second transmitter 30 is configured to transmit a serial data stream on the basis of a second transmitting clock. The frequency of the second transmitting clock corresponds to the frequency of the receiving clock. The frames transmitted by the first transmitter 40 comprise nine parallel data bits, and the frequency of the first transmitting clock hence corresponds on average to 1/9^{th} times the frequency of the receiving clock and the second transmitting clock.

In FIG. 1, data registers of the ring buffer which are used for storing the received data bits are numbered from 0 to 19. A write pointer 51 indicates the position of the data register for storing the next data bit received by the receiver 20. A first read pointer 52 indicates the position of the first data bit of a data frame to be transmitted by the first transmitter 40. A second read pointer 53 indicates the position of the data bit to be transmitted by the second transmitter 30. The section of the ring buffer containing new data bits which have been received by the receiver 20 but not yet been transmitted by the first transmitter 40 is indicated at 76. The section of the ring buffer 50 containing the frame to be transmitted by the first transmitter 40 is indicated at 74. The section 74 starts at the position of the first read pointer 52 and comprises nine data registers. The section of the ring buffer 50 containing old data bits which have already been transmitted by the first transmitter, but have not yet been overwritten with new data bits is indicated at 72.

As further explained below, the ring buffer 50 has a specific segmented structure (i.e., is subdivided into four cyclic registers). Each of the cyclic registers is operated on the basis of a divided clock having a frequency which corresponds to ¼ times the frequency of the receiving clock and the second transmitting clock. Hence, the ring buffer 50 is implemented on the basis of components which operate at a frequency which is significantly smaller than the frequency of the receiving clock and the transmitting clock. As a result, higher frequencies can be used for the receiving clock and the second transmitting clock.

For retransmitting the stored data bits from the ring buffer 50 on the basis of the second transmitting clock, a group of four data bits is provided to the second transmitter 30, each of the four bits coming from a different cyclic register. The second transmitter 30 then merges the group of four data bits to a serial data stream. The section of the ring buffer 50 containing the group of data bits starts at the position of the second read pointer and is indicated at 78.

In one embodiment, the device of FIG. 1 is operated as follows. Data bits are sequentially stored in the ring buffer 50 at each clock cycle of the receiving clock, the write pointer being advanced by one position at each clock cycle. At each cycle of the first transmitting clock, nine data bits are read out in parallel from the ring buffer 50, and the first read pointer is advanced by nine positions. At each cycle of a divided clock corresponding to one of the cyclic registers, a group of four data bits is supplied from the ring buffer 50 to the second transmitter 30, and the second read pointer 53 is advanced by four positions. In the illustration of FIG. 1, the write pointer 51 and the first and second read pointers 52, 53 are advanced in the clockwise direction. After the data bits have been transmitted by the first transmitter 40 and the second transmitter 30, they are overwritten with new data bits in the course of advancing the write and read pointers 51, 52, 53. The cyclic structure of the ring buffer means that the write pointer 51 and the read pointers 52 and 53 are moved from a bit position at the end of the ring buffer to a bit position at the beginning of the ring buffer if the pointer is advanced over the last bit position (i.e., having reached the bit position with number 19).

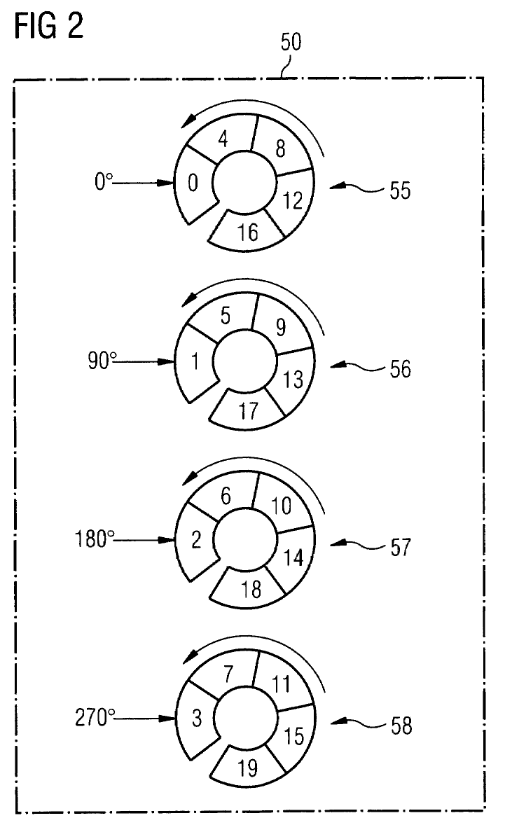

FIG. 2 schematically illustrates one embodiment of a subdivision of the ring buffer 50 into four cyclic registers. In FIG. 2, the cyclic registers are indicated at 55, 56, 57, and 58. Again, the data registers of the ring buffer 50 for storing the data bits are numbered from 0 to 19. As illustrated, adjacent data registers or data registers containing adjacent data bits are located in different cyclic registers. Namely, a first cyclic register 55 contains data registers 0, 4, 8, 12, and 16. A second cyclic register 56 contains data registers 1, 5, 9, 13, and 17. A third cyclic register 57 contains data registers 2, 6, 10, 14, and 18. A fourth cyclic register 58 contains data registers 3, 7, 11, 15, and 19.

Each of the cyclic registers 55, 56, 57, 58 is operated on the basis of a corresponding divided clock. With respect to the divided clock of the first cyclic register 55, the divided clock of the second cyclic register 56 is phase-shifted by 90°. This phase shift corresponds to ¼th times the cycle of the divided clocks or to a full cycle of the receiving clock or second transmitting clock. The divided clock corresponding to the third cyclic register 57 is phase-shifted with respect to the divided clock of the first cyclic register 55 by 180°. The divided clock corresponding to the fourth cyclic register 58 is phase-shifted with respect to the divided clock corresponding to the first cyclic register 55 by 270°. Accordingly, the divided clocks corresponding to the cyclic registers 55, 56, 57, 58 are phase-shifted with respect to the divided clock corresponding to that cyclic register containing adjacent data bits by 90°.

For storing data in the cyclic registers 55, 56, 57, 58, a corresponding write pointer of each cyclic register 55, 56, 57, 58 is advanced by one position at each cycle of the corresponding divided clock. In FIG. 2, this is illustrated by a counter-clockwise rotation of the cyclic registers 55, 56, 57, 58 with respect to the horizontal arrows. In other words, data bits are stored in the ring buffer at a rate of one bit per each clock cycle of the divided clocks, which corresponds to a rate of one bit per each cycle of the receiving clock.

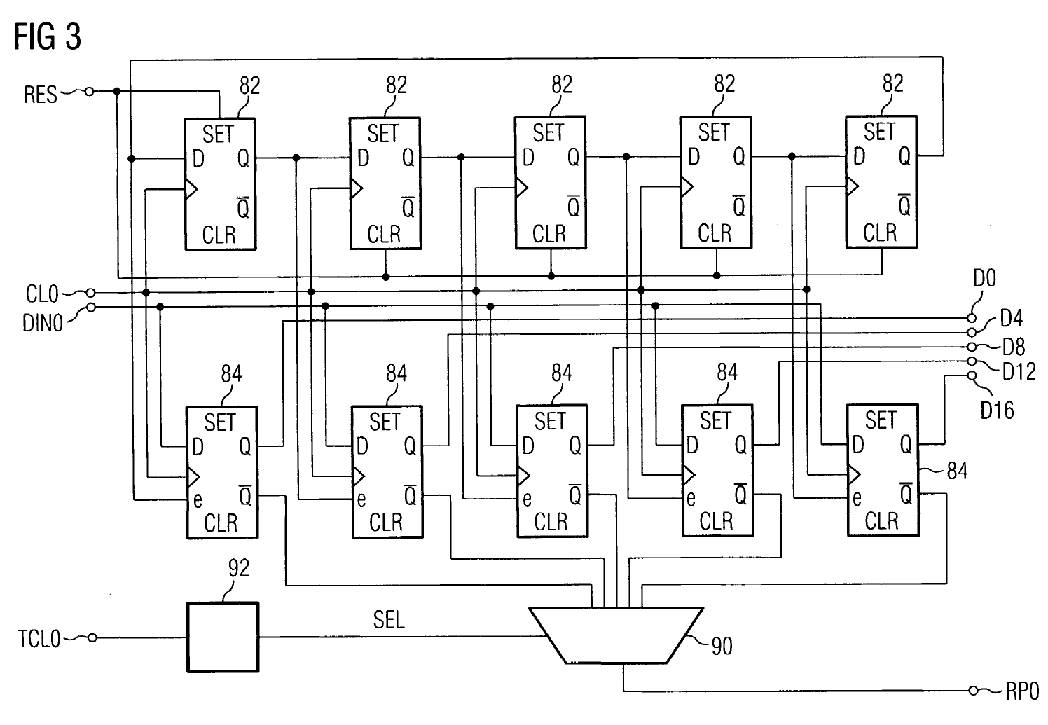

FIG. 3 schematically illustrates one embodiment of circuitry configured to implement a cyclic register as illustrated in FIG. 2. By way of example, the first cyclic register 55 is specifically illustrated in FIG. 2. The other cyclic registers 56, 57, and 58 can each be implemented with a similar configuration.

As illustrated in FIG. 3, the example cyclic register comprises a series of data registers 84 for storing the data bits. The data registers 84 are enabled in a sequential manner via a shift register formed by a series of D-flip-flops 82. Each of the data registers 84 provides a corresponding output to the parallel output of the cyclic register. The output signals of the cyclic register are indicated at D0, D4, D8, D12, and D16, corresponding to the data registers 0, 4, 8, 12, 16 of the cyclic register 55 as illustrated in FIG. 2. A second, complementary, output is provided from the data registers 84 to a multiplexer 90. The multiplexer 90 is controlled by a select signal SEL in such a manner that one of the outputs of the data registers 84 is provided as a repeat output signal RP0 of the cyclic register. Together with corresponding repeat output signals of the other cyclic register 56, 57, 58, the repeat output signal RP0 forms the group of four data bits supplied to the second transmitter 30. Accordingly, the select signal SEL controls the position of the second read pointer 53 in FIG. 1.

The select signal SEL is generated on the basis of an input clock signal TCL0. For this purpose, the circuit comprises a repeat select logic 95. The repeat select logic 95 may have a configuration which is similar to that of the shift register for enabling the data registers 84.

As mentioned above, a shift register is used to sequentially enable the data registers 84 for storing data. The shift register is formed by connecting the data output of one of the D-flip-flops 82 to the data input of the next D-flip-flop 82 in such a way that a series of D-flip-flops 82 is formed, and by connecting the data output of the last D-flip-flop 82 of the series to the data input of the first D-flip-flop of the series. A reset signal RES is supplied to a SET-input of the first D-flip-flop 82 and to a CLR-input of the other D-flip-flops 82. Via the SET-input, the state of the D-flip-flop 82 can be set in such a way that the data output is active. Via the CLR-input, the state of the D-flip-flop 82 can be set in such a way that the state of the data output is inactive. Consequently, via the reset signal RES the shift register can be initialized in such a way that only one of the D-flip-flops 82 has its output in an active state.

In FIG. 3, the data inputs of the D-flip-flops 82 and the data registers 84 are indicated by D. The data outputs are indicated Q, and the complementary data outputs are indicated by Q̅.

In FIG. 3, the clock signal corresponding to the divided clock of the first cyclic register 55 is indicated by RCL0. The clock signal RCL0 is supplied to the clock inputs of the D-flip-flops 82 of the shift register and to the clock inputs of the data registers 84. Consequently, at each cycle of the clock signal RCL0, the active state at the output of one of the D-flip-flops 82 of the shift register is shifted from one D-flip-flop 82 to the next D-flip-flop 82 of the series, and from the last D-flip-flop 82 of the series to the first D-flip-flop 82 of the series.

The signals at the inputs and outputs of the D-flip-flops 82 of the shift register are used to generate corresponding enable signals for the data registers 84. For this purpose, the data inputs of the D-flip-flops 82 of the shift register are respectively connected to an enable input of a corresponding data register 84. In FIG. 3, the enable inputs of the data registers 84 are indicated by e. As a result, only one of the data registers 84 at a time is enabled to store data available from a data input signal DIN0 supplied to its data input. The position of this data register 84 is advanced from one data register 84 to the next at each cycle of the clock signal RCL0. At the same time, the data stored in the data registers 84 is available at the corresponding data outputs of the data registers 84.

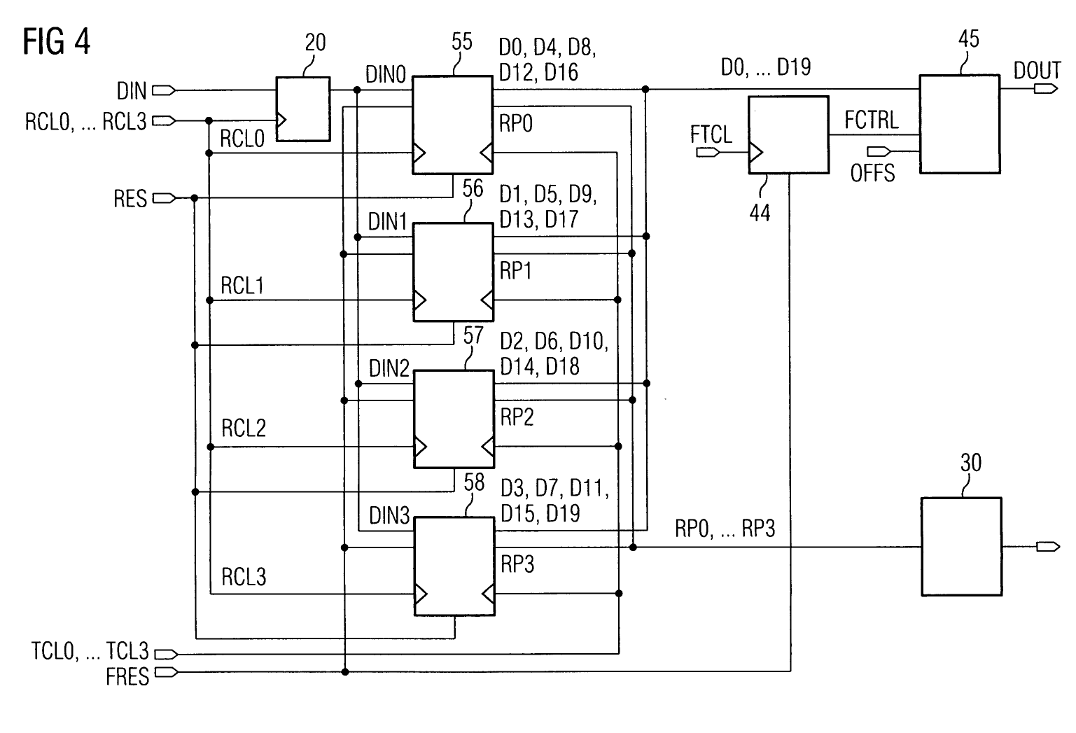

FIG. 4 schematically illustrates an overview diagram of one embodiment of a device configured to transmit data between different clock domains. As illustrated, the device comprises the cyclic registers 55, 56, 57, and 58. In one embodiment, the cyclic registers are each configured as illustrated in FIG. 3. The data is received via a data input signal DIN, from which four individual data input signals DIN0, DIN1, DIN2, and DIN3 are extracted for being supplied to the cyclic registers 55, 56, 57, and 58. The first cyclic register receives the data input signal DIN0 and outputs parallel data signals D0, D4, D8, D12, D16 and a repeat output signal RP0. The second cyclic register 56 receives the data input signal DIN1 and outputs parallel data signals D1, D5, D9, D13, D17 and a repeat output signal RP1. The third cyclic register 57 receives the data input signal DIN2 and outputs parallel data signals D2, D6, D10, D14, D18 and a repeat output signal RP2. The fourth cyclic register 58 receives the data input signal DIN3 and outputs parallel data signals D3, D7, D11, D15, D19 and a repeat output signal RP3. The parallel data signals D0-D19 correspond to the data registers 0 to 19 of the ring buffer. The repeat output signals RP0 to RP3 correspond to the group of data bits transmitted from the ring buffer to the second transmitter 30.

As illustrated in FIG. 4, the device is supplied with four individual clock signals RCL0-RCL3 which correspond to the respective divided clocks of the cyclic registers 55, 56, 57, 58. The clock signals RCL0-RCL3 are phase-shifted with respect to each other as explained with reference to FIG. 2. In one embodiment, only one of the clock signals (e.g., the clock signal CL0) is actually received in the memory module from the memory controller or the adjacent memory module, and the other clock signals are generated therefrom. Of course, it is also possible to transmit each of the clock signals RCL0-RCL3 together with the data signal DIN.

The clock signal RCL0 is supplied to the first cyclic register 55. The clock signal RCL1 is supplied to the second cyclic register 56. The clock signal RCL2 is supplied to the third cyclic register 57, and the clock signal RCL3 is supplied to the fourth cyclic register 58.

Further, the device is supplied with four clock signals TCL0-TCL3 which are related to the second transmitting clock in the same way as the clock signals RCL0-RCL3 are related to the receiving clock. That is to say, the clock signals TCL0-TCL3 each have a frequency which corresponds to ¼th times the frequency of the second transmitting clock, and the clock signals TCL0, TCL2, and TCL3 are phase-shifted with respect to the clock signal TCL0 by 90°, 180°, and 270°, respectively. The clock signal TCL0 is supplied to the first cyclic register 55, the clock signal TCL1 is supplied to the second cyclic register 56, the clock signal TCL2 is supplied to the third cyclic register 57, and the clock signal TCL3 is supplied to the fourth cyclic register 58. In the cyclic registers 55, 56, 57, 58, the clock signals TCL0, TCL1, TCL2, and TCL3, respectively, are used to generate the select signal SEL for the multiplexer 90 by means of the repeat select logic 95. In particular, the select signal SEL for the multiplexer 90 is generated in such a way that the data output of a different data register 84 is selected at each cycle of the clock signal TCL0. In particular, the data outputs of the data registers 84 are subsequently selected in a similar way as they are enabled for storing data.

In one embodiment, the clock signals TCL0-TCL3 are generated within the memory module in such a way that they have a suitable phase shift with respect to the clock signals RCL0-RCL3.

FIG. 4 also illustrates the receiver 20, which samples the data input signal DIN on the basis of the four clock signals RCL0-RCL3, so as to generate the respective data input signals DIN0, DIN1, DIN2, DIN3 of the cyclic registers 55, 56, 57, and 58, respectively.

Also illustrated in FIG. 4 is a frame counter 44 which is operated on the basis of a frame transmitting clock signal FTCL. The frame transmitting clock signal FTCL corresponds to the first transmitting clock, and may be generated from one of the clock signals RCL0-RCL3 by means of frequency division techniques. The frame counter 44 supplies a frame control signal FCTRL to a frame select logic 45 which selects a group of nine data signals from the data signals D0-D19 to be supplied as parallel data output signal DOUT to the memory core. The frame select logic 45 is further supplied with an offset signal OFFS, which can be used to adjust the relative position of the first read pointer 52 and the write pointer 51. The frame counter 44 and the frame select logic 45 form part of the first transmitter 40 as illustrated in FIG. 1.

FIG. 4 also illustrates the second transmitter 30, which receives the repeat output signals RP0-RP3 from the cyclic registers 55-58 so as to merge them to a serial data stream which is transmitted on the basis of a second transmitting clock. The cyclic registers 55, 56, 57, 58 can be reset and initialized via the reset signal RES. The frame counter 44 can be reset and initialized by means of a frame reset signal FRES.

The above-explained embodiments of transmitting data between different clock domains have significant advantages as compared to the existing solutions. In particular, the above embodiments can provide a low latency as they allow for crossing from one receiving clock domain to two transmitting clock domains in one operation. The latency can be adjusted for each crossing in steps of one bit position. In this way, it is possible to provide just enough headroom for a phase-shift existing between the receiving clock domain and the transmitting clock domains. The receiving clock and the second transmitting clock can be adjusted so as to have a constant phase difference. Further, in the embodiments explained above, it is provided for that the fastest circuits necessary to implement the invention operate at a comparatively slow clock frequency corresponding to ¼th times the full frequency of the receiving clock and the second transmitting clock (i.e., the receiving clock and the second transmitting clock form virtual clock signals which are not distributed within the device in the form of an actual clock signal having the full frequency).

In certain embodiments, the above-explained device can easily be scaled to accommodate different sizes of the ring buffer. In particular, the size of the ring buffer can be changed in steps of four bits by adding or removing one bit from each of the cyclic registers.

In one embodiment, a different number of cyclic registers could be used. Further, the above embodiments could be used in other applications than memory devices.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method of transmitting data between different clock domains, the method comprising:
receiving data bits on the basis of a receiving clock;
sequentially storing the data bits in a ring buffer;
simultaneously transmitting a number of the stored data bits from the ring buffer on the basis of a first transmitting clock; and
transmitting the stored data bits from the ring buffer on the basis of a second transmitting clock.

2. The method according to claim 1, wherein the number of data bits simultaneously transmitted from the ring buffer is an odd number.

3. The method according to claim 2, wherein the number of data bits simultaneously transmitted from the ring buffer is nine.

4. The method according to claim 1, wherein sequentially storing the data bits in the ring buffer comprises:
accessing the ring buffer for write operations on the basis of a write pointer and advancing the write pointer by one bit position at each cycle of the receiving clock.

5. The method according to claim 1, wherein simultaneously transmitting the number of the stored data bits from the ring buffer comprises:
accessing the ring buffer for read operations on the basis of a first read pointer and advancing the first read pointer by a number of bit positions corresponding to the number of data bits at each cycle of the first transmitting clock.

6. The method according to claim 1, wherein transmitting the stored data bits from the ring buffer comprises:
accessing the ring buffer for read operations on the basis of a second read pointer.

7. The method according to claim 1, wherein the frequency of the second transmitting clock corresponds to the frequency of the receiving clock.

8. The method according to claim 1, wherein the ring buffer is subdivided into a number of N cyclic registers in such a way that adjacent bits of the ring buffer are located in different cyclic registers, and wherein the method comprises:
accessing the cyclic registers for write operations on the basis of a corresponding divided clock having 1/N^{th} times the frequency of the receiving clock and advancing a corresponding write pointer of each cyclic register at each cycle of the corresponding divided clock.

9. The method according to claim 8, wherein the number N of cyclic registers is four.

10. The method according to claim 8, wherein the divided clocks corresponding to the different cyclic registers are phase-shifted with respect to each other.

11. The method according to claim 10, wherein the phase shift between the divided clocks of cyclic registers containing adjacent bits of the ring buffer corresponds to 1/N^{th} times the clock cycle of the divided clocks.

12. The method according to claim 8, wherein transmitting the stored data bits from the ring buffer comprises:
accessing the ring buffer for read operations on the basis of a second read pointer and advancing the read pointer by a number of bit positions corresponding to the number N of cyclic registers at each clock cycle of one of the divided clocks.

13. A device configured to transmit data between different clock domains, the device comprising:
a receiver configured to receive data bits on the basis of a receiving clock;
a ring buffer configured to sequentially store the data bits;
a first transmitter configured to simultaneously transmit a number of the stored data bits from the ring buffer on the basis of a first transmitting clock; and
a second transmitter configured to transmit the stored data bits from the ring buffer on the basis of a second transmitting clock.

14. The device according to claim 13, wherein the ring buffer is configured to sequentially store the data bits on the basis of a write pointer, configured to advance by one bit position at each cycle of the receiving clock.

15. The device according to claim 13, wherein the ring buffer is configured to be accessed for simultaneously reading out the number of data bits on the basis of a first read pointer which is advanced by a number of bit positions corresponding to the number of data bits at each cycle of the first transmitting clock.

16. The device according to claim 13, wherein the ring buffer is configured to be accessed for reading out the stored data bits on the basis of a second read pointer.

17. The device according to claim 13, wherein the frequency of the second transmitting clock corresponds to the frequency of the receiving clock.

18. The device according to claim 13, wherein the ring buffer is subdivided into a number of N cyclic registers in such a way that adjacent bits of the ring buffer are located in different cyclic registers; and
wherein the cyclic registers are configured to be accessed for write operations on the basis of a corresponding divided clock having 1/N times the frequency of the receiving clock, a corresponding write pointer of each cyclic register being advanced at each cycle of the corresponding divided clock.

19. The device according to claim 18, wherein the divided clocks corresponding to the different cyclic registers are phase-shifted with respect to each other.

20. The device according to claim 19, wherein the phase shift between the divided clocks of cyclic registers containing adjacent bits of the ring buffer corresponds to 1/N^{th} times the clock cycle of the divided clocks.

21. The device according to claim 18, wherein the ring buffer is configured to be accessed for read operations on the basis of a second read pointer, the second read pointer being advanced by a number of bit positions corresponding to the number N of cyclic registers at each clock cycle of one of the divided clocks.

22. The device according to claim 18, wherein the ring buffer comprises a number of data registers configured to store the data bits and a shift register configured to sequentially enable one of the data registers for storing the data bits.

23. The device according to claim 18, wherein each of the cyclic registers comprises a number of data registers configured to store the data bits and a shift register configured to sequentially enable one of the data registers for storing the data bits.

24. A memory module, comprising:
a memory core configured to store data;
a receiver configured to receive data bits from a memory controller or a further memory module on the basis of a receiving clock;
a ring buffer configured to sequentially store the data bits;
a first transmitter configured to simultaneously transmit a number of the stored data bits from the ring buffer to the memory core on the basis of a first transmitting clock; and
a second transmitter configured to transmit the stored data bits from the ring buffer to a further memory module on the basis of a second transmitting clock.

25. An apparatus for transmitting data between different clock domains, the apparatus comprising:
means for receiving data bits based on a receiving clock;
means for sequentially storing the data bits in a ring buffer;
means for simultaneously transmitting a number of the stored data bits from the ring buffer based on a first transmitting clock; and
means for transmitting the stored data bits from the ring buffer based on a second transmitting clock.
